(19) United States
(12) Patent Application Publication
(10) Pub. No.: US 2020/0176495 A1
(43) Pub. Date: Jun. 4, 2020

(54) IMAGE SENSOR, FABRICATING METHOD THEREOF, AND IMAGING DEVICE

(71) Applicant: HUAIAN IMAGING DEVICE MANUFACTURER CORPORATION, Huaian (CN)

(72) Inventors: Tim WANG, HUAIAN (CN); Zhiwei LI, HUAIAN (CN); Tony RAN, HUAIAN (CN); Leo HUANG, HUAIAN (CN)

(73) Assignee: HUAIAN IMAGING DEVICE MANUFACTURER CORPORATION, HUAIAN (CN)

(21) Appl. No.: 16/702,093

(22) Filed: Dec. 3, 2019

(30) Foreign Application Priority Data
Dec. 4, 2018 (CN) 201811468871.0

(51) Int. Cl. H01L 27/146

(52) U.S. Cl. CPC H01L 27/14609; H01L 27/14627; H01L 27/14621; H01L 27/14683; H01L 27/1463; H01L 27/14645; H01L 27/14636

(57) ABSTRACT

An image sensor comprising a substrate including a logic region and a pixel region, wherein the logic region is configured to form at least a portion of an active logic device therein, the pixel region is configured to form a pixel unit therein, the pixel unit including at least a photosensitive element, wherein an upper surface of the logic region is lower than an upper surface of the pixel region.

### CROSS REFERENCE TO THE RELATED APPLICATION

The present application claims priority to the Chinese application No. 201811468871.0, filed on Dec. 4, 2018, which is herein incorporated by reference in its entirety.

### TECHNICAL FIELD

The present disclosure relates to an image sensor, a method of fabricating the same, and an imaging device.

### BACKGROUND

In a back-illuminated image sensor, logic devices and photosensitive elements are generally formed on a same surface of the substrate. However, there is a pad portion (including pad(s) and conductive structure(s) between the pad(s) and the active region of the substrate) over the logic region, causing a height difference between the logic region and the pixel region. Due to the height difference, usually there is an area around the pad within a distance of 200 μm to 300 μm or more from the pad, and if a pixel is formed in the area the evenness is poor when the color filter is formed. Therefore, this area is difficult to be effectively utilized.

In addition, in the case that a color filter is formed in the area close to the pad, since the surface of the color filter has a certain slope, the microlens that is disposed above the area may be tilted. This also makes this area difficult to be used.

Therefore, there is a need for improved image sensor, fabrication method thereof, and imaging device.

### SUMMARY

According to an aspect of the present disclosure, there is provided an image sensor comprising: a substrate including a logic region and a pixel region, wherein the logic region is configured to form at least a portion of an active logic device therein, the pixel region is configured to form a pixel unit therein, the pixel unit including at least a photosensitive element, wherein an upper surface of the logic region is lower than an upper surface of the pixel region.

In some embodiments, the image sensor further comprises: a color filter layer, the color filter layer including a plurality of color filters each being disposed over a respective pixel unit; and a microlens array including a plurality of microlenses each being disposed over a respective color filter.

In some embodiments, a portion of the substrate is removed to form the upper surface of the logic region.

In some embodiments, the image sensor further comprises: a connection structure disposed over the logic region, the connection structure including at least one insulating layer and at least one conductive member; and a pad disposed over the connection structure.

In some embodiments, the image sensor further comprises: a connection structure disposed over the logic region, the connection structure including at least one insulating layer and at least one conductive member; and a pad disposed over the connection structure, wherein a distance between the pad and a microlens which is immediately adjacent to the pad is less than or equal to 200 μm.

In some embodiments, the image sensor further comprises: a functional layer over the pixel region, the functional layer comprising at least an insulating layer.

In some embodiments, the image sensor further comprises: a functional layer over the pixel region; a color filter layer including a plurality of color filters each being disposed over a respective pixel unit, the functional layer being disposed between corresponding color filter(s) and corresponding pixel unit(s); and a microlens array including a plurality of microlenses each being disposed over a respective color filter.

According to an aspect of the present disclosure, there is provided a method for fabricating an image sensor, comprising: providing a substrate having a first major surface and a second major surface opposite to the first major surface, the substrate including a logic region and a pixel region, the logic region for forming at least a portion of an active logic device therein, and the pixel region for forming a pixel unit therein; removing an upper portion of the logic region in a direction from the second major surface toward the first major surface such that an upper surface of the logic region is lower than an upper surface of the pixel region; and forming a pixel unit in the pixel region, wherein the pixel unit includes at least a photosensitive element.

In some embodiments, the method further comprises: forming part of or all of the active logic device in the logic region where the upper portion is removed.

In some embodiments, the method further comprises: forming a functional layer over the pixel region, the functional layer including at least an insulating layer.

In some embodiments, the method further comprises: forming a color filter layer including a plurality of color filters each of which is disposed over a respective pixel unit; forming a microlens array including a plurality of microlenses each of which is disposed over a respective color filter.

In some embodiments, the method further comprises: forming a color filter layer including a plurality of color filters each of which is disposed over a respective pixel unit, the functional layer being disposed between corresponding color filter(s) and corresponding pixel unit(s); forming a microlens array including a plurality of microlenses each of which is disposed over a respective color filter.

In some embodiments, the method further comprises: forming a connection structure over the logic region from which the upper portion is removed, the connection structure including at least one insulating layer and at least one conductive member; and forming a pad over the connection structure.

In some embodiments, the method further comprises: forming a connection structure over the logic region from which the upper portion is removed, the connection structure including at least one insulating layer and at least one conductive member; and forming a pad over the connection structure, wherein a distance between the pad and a microlens directly adjacent to the pad is less than or equal to 200 μm.

In some embodiments, the method further comprises: forming a connection structure over the logic region from which the upper portion is removed, the connection structure including at least one insulating layer and at least one conductive member; and forming a pad over the connection structure, wherein a distance between the pad and a microlens directly adjacent to the pad is less than or equal to 200 μm.

In some embodiments, forming a pixel unit in the pixel region comprises: forming a trench isolation in the pixel region to separate the pixel units; and forming a photosensitive element of the pixel unit in a region of the pixel region separated by the trench.

According to an aspect of the present disclosure, there is provided an apparatus comprising an image sensor according to any of the embodiments of the present disclosure.

### BRIEF DESCRIPTION OF THE DRAWINGS

The drawings, which constitute a part of the specification, illustrate exemplary embodiments of the present disclosure, and together with the Descriptions serves to explain the principles of the present disclosure.

FIG. 1 illustrates a partial cross-sectional view of a conventional image sensor;

FIG. 2A illustrates a partial cross-sectional view of an image sensor in accordance with some embodiments of the present disclosure;

FIG. 2B illustrates a partial cross-sectional view of an image sensor in accordance with some embodiments of the present disclosure;

FIG. 3 illustrates a partial cross-sectional view of an image sensor in accordance with some embodiments of the present disclosure;

FIGS. 4A-4G are partial cross-sectional views illustrating some steps of a method of fabricating an image sensor in accordance with some embodiments of the present disclosure;

FIG. 5 illustrates a flow diagram of an exemplary method of fabricating an image sensor in accordance with some embodiments of the present disclosure; and

FIG. 6 illustrates a schematic block diagram of an imaging device in accordance with some embodiments of the present disclosure.

Note that, in the following illustrative implementations, in some cases the same portions or portions having a same function are denoted by a same reference numeral in different drawings, and description of such portions will not be repeated. In the present specification, similar reference numerals and letters are used to refer to similar items, therefore once an item is defined in one figure, it need not be further discussed for following figures.

In order to facilitate understanding, positions, sizes, ranges, and the like of respective structures illustrated or described in the drawings and the like are not intended to represent the actual positions, sizes, ranges, and the like in some cases. Therefore, the disclosed inventions shall not be limited to the positions, the sizes, the ranges, and the like as disclosed in the drawings and the like.

### DETAILED DESCRIPTION OF ILLUSTRATIVE EMBODIMENTS

Various exemplary embodiments of the present disclosure will now be described in detail with reference to the accompanying drawings. It should be noted that the relative arrangement of components or steps, the numerical expressions, and numerical values set forth in these embodiments are not intended to limit the scope of the present disclosure unless it is specifically stated otherwise. In addition, techniques, methods, and apparatus as known by those skilled in the art may be not discussed in detail, but those techniques, methods, and apparatus should be regarded as a part of the specification where appropriate.

Further, it should be understood that, the terms “comprise” or “include” and its variants, as used herein, specify the presence of indicated features, integers, steps, operations, units and/or components, but do not preclude the presence or addition of one or more other features, integers, steps, operations, units and/or components, and/or any combinations thereof.

The terms such as “front”, “back”, “top”, “bottom”, “over”, “under” and the like, as used in the specification and claims, if any, are used for descriptive purpose and not necessarily for describing permanent relative positions. It should be understood that such terms as used can be interchangeable under appropriate circumstances, so that the embodiments of the present disclosure described herein are, for example, capable of operating in other orientations than those illustrated or described herein.

In the present disclosure, the term “provide” or its variants are intended in a broad sense to embrace all the ways of obtaining an object, therefore “providing an object” includes but is not limited to “purchasing”, “preparing/manufacturing”, “disposing/arranging”, “installing/assembling”, and/or “ordering” the object, or the like.

In addition, certain terminology may also be used in the following description for purpose of reference only, and thus are not intended to be limiting. For example, the terms “first”, “second”, and other such numerical terms leading a structure or element do not imply any sequence or order unless expressly indicated otherwise by the context.

The following description of the exemplary embodiments is illustrative only and is not intended to limit the present disclosure or any application and usage thereof.

Hereinafter, description will be given in association with some embodiments of the present disclosure with a CMOS image sensor as an example, however, the present disclosure is not intended to be limited thereto.

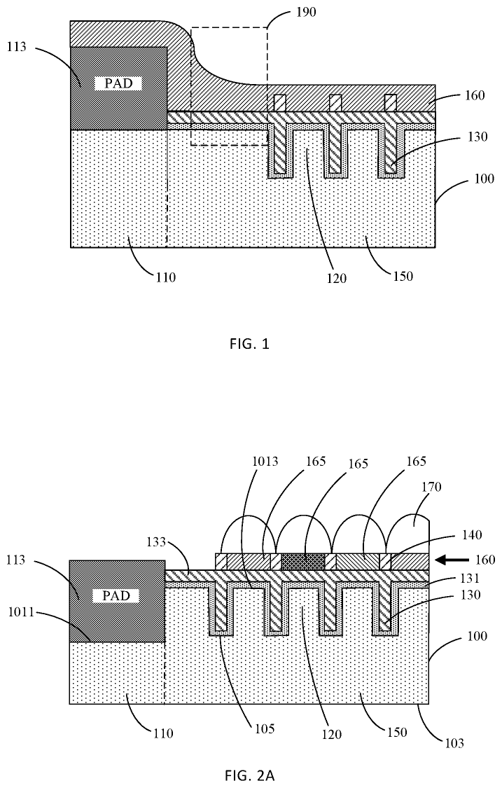

FIG. 1 illustrates a partial cross-sectional view of a conventional image sensor in accordance with the prior art. As shown in FIG. 1, a conventional image sensor may include a substrate 100. The substrate 100 may include a logic region 110 and a pixel region 150. Those skilled in the art will readily appreciate that generally the logic region can be used to form at least a portion (e.g., an active region) of an active logic device (not shown in the figure). Typically, a pixel region can be used to form a pixel unit therein. Generally, the pixel unit includes at least a photosensitive element 120 such as a photodiode or the like.

As shown in FIG. 1, a pad (PAD) is formed over the logic region, causing a height difference between the logic region and the pixel region. When the color filter layer 160 is formed over the pixel region, the color filter, which is formed in the vicinity of the pad, for example, generally within 200 μm to 300 μm or more from the pad, has an uneven surface due to the existence of the height difference. For example, as shown in the figure, the color filter has a slope in the vicinity of the pad as shown in the area 190 indicated by dashed box. Therefore, such an area is difficult to be utilized to form pixels therein. Further, when the microlens array is further formed over the color filter, if the microlens is disposed above this area the microlens will be tilted since the surface of the color filter has the slope. This also makes this area difficult to be used.

Thus, conventionally this portion of the substrate near the pad, such as region 190, is difficult to be utilized to fabricate pixels therein. Thereby, a part of the area of the substrate cannot be effectively utilized, so that the area of the pixel region is limited.

For alleviating or overcoming parts or all of the above problems, the inventions of the present disclosure are proposed.

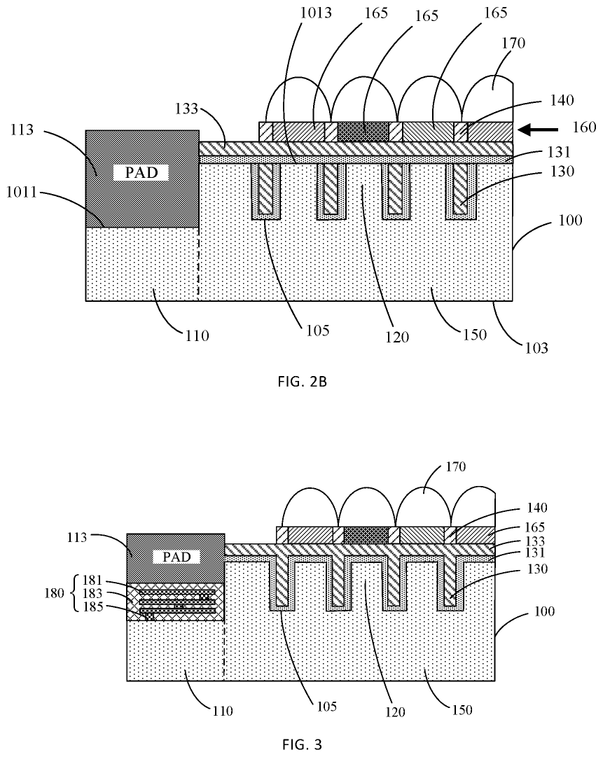

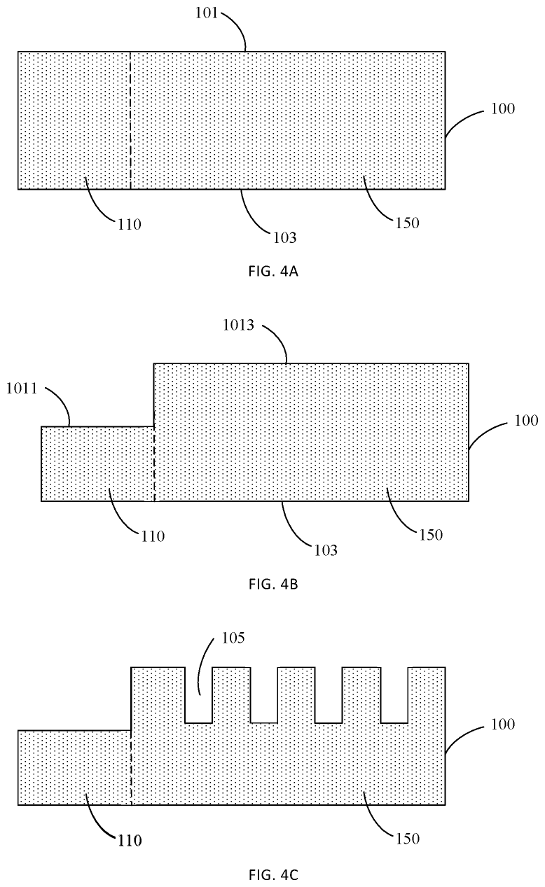

FIG. 2A illustrates a partial cross-sectional view of an image sensor in accordance with some embodiments of the present disclosure. As shown in FIG. 2A, the image sensor of some embodiments of the present disclosure may include a substrate 100. The substrate 100 may include a logic region 110 and a pixel region 150. The logic region is configured for forming at least a portion of an active logic device therein. The pixel region is configured for forming a pixel unit 120 therein.

The substrate 100 may be, for example, a semiconductor substrate. Here, there is no particular limitations on the substrate as long as it can be used to fabricate a photosensitive member and a logic device. Additionally, a substrate comprising a semiconductor material is referred to herein as a semiconductor substrate, such as but not limited to, a bulk semiconductor substrate.

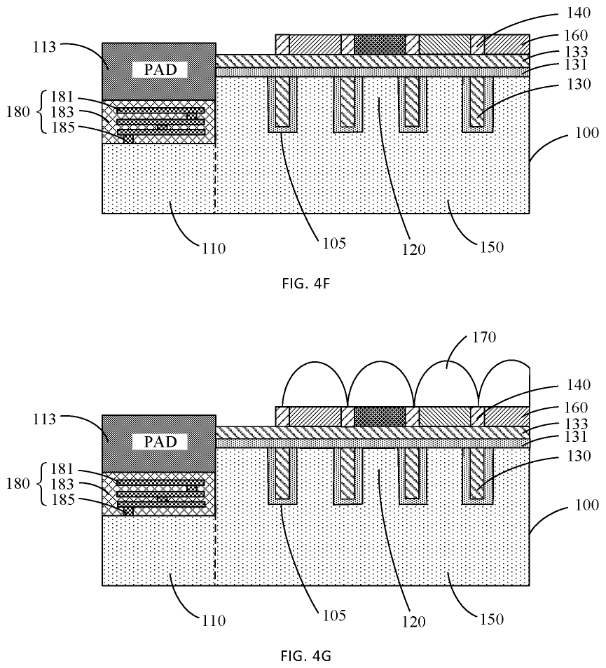

The substrate 100 has a first major surface 101 and a second major surface 103 opposite to the first major surface, as best seen from FIGS. 2A, 4A, and 4B, for example.

The pixel unit may include at least a photosensitive element such as a photodiode. In other embodiments, the pixel unit may also include other components associated with the photosensitive element, such as a switching element, a charge storage element, and the like. In FIG. 2A, four pixel units 120 are schematically illustrated; however, the present disclosure shall not be limited thereto. In other embodiments, more or fewer pixel units may be included.

As shown in the figure, the upper surface 1011 of the logic region is lower than the upper surface 1013 of the pixel region (as can be better seen from FIG. 4B). In other words, in the direction from the second major surface 103 toward the first major surface 101, the upper surface 1011 of the logic region is disposed closer to the second major surface 103 than the upper surface 1013 of the pixel region (or pixel unit).

In some embodiments, the logic region is thinned from the first major surface relative to the pixel region.

The image sensor may also include a color filter layer 160. As shown in the figure, the color filter layer 160 may include a plurality of color filters 165 each of which may be disposed over a respective pixel unit. The color filters may include, for example but not limited to, a red color filter, a green color filter, and a blue color filter. As shown in the figure, the color filter layer 160 may further include a separation member 140 for separating the color filters. In some embodiments, the separation member 140 can be formed of, for example, a metal.

The image sensor may also include a microlens array 170. As shown in the figure, the microlens array 170 may include a plurality of microlenses each of which is disposed above a corresponding color filter.

In some embodiments, an active logic device can be formed to adjoin or be adjacent to an upper surface of the logic region. For example, the active logic device can be a transistor (e.g., a MOS transistor) whose channel region, source region, and/or drain region can be formed to adjoin or be adjacent to the upper surface of the logic region. Additionally, in some embodiments, a photosensitive element (e.g., a photodiode) can be formed to adjoin or adjacent to an upper surface of the pixel region. For example, the photodiode 120 may include doped regions of opposite conductivity types, one of which may be formed to adjoin or be adjacent to an upper surface of the pixel region.

The image sensor may also include a functional layer that is associated with the pixel region. In some embodiments, the functional layer may include isolation and protection structure(s). The isolation and protection structure may include at least one insulating layer. In the embodiment shown in FIG. 2A, the isolation and protection structure may include a first insulating layer 131 and a second insulating layer 133 over the insulating layer 131. The first insulating layer 131 and the second insulating layer 133 fill the isolation trenches 105 in the substrate (as best seen in FIG. 4C). Thus, the isolation and protection structure can include portions located in the substrate and portions above the substrate, as schematically illustrated by dashed lines in the figures. In some embodiments, the first insulating layer may be formed of, for example, silicon nitride, and the second insulating layer may be formed of, for example, silicon oxide; it should be understood that the present disclosure is not limited thereto.

In some embodiments, the functional layer may further include an anti-reflection layer (not shown in the drawing) or the like.

Here, in FIG. 2A and some other figures, the color filter layer and the microlens array are not illustrated in the portion immediately adjacent to the pad (PAD). It should be understood that the present disclosure is not limited thereto. In fact, a photodiode can also be formed in the portion of the pixel region which is adjacent to the pad. In various embodiments, the color filter layer and microlens array can be configured to extend all the way to adjoin or be adjacent to the PAD.

FIG. 2B illustrates a partial cross-sectional view of an image sensor in accordance with further embodiments of the present disclosure. The constituent substrate of the image sensor of the embodiment shown in FIG. 2B is the same as or similar to that shown in FIG. 2A except that the isolation and protection structures are different. Therefore, the same components of the image sensor of the embodiment shown in FIG. 2B as those shown in FIG. 2A will not be repeatedly described herein.

As shown in FIG. 2B, the isolation and protection structure of the image sensor may include a first portion 130 in the substrate and a second portion over the substrate (which may include the layer 131 and the layer 133). In this embodiment, the first portion 130 may include at least one insulating layer. In this embodiment, the first portion 130 may similarly include two insulating layers, one of which may be formed of, for example, silicon nitride, and the other may be formed of, for example, silicon oxide. The second portion of the isolation and protection structure may also include at least one insulating layer. In this embodiment, the second portion may similarly include two insulating layers, one of which (for example, 131) may be formed of, for example, silicon nitride, and the other (133) may be formed of, for example, silicon oxide. It should be understood that the present disclosure is not limited thereto.

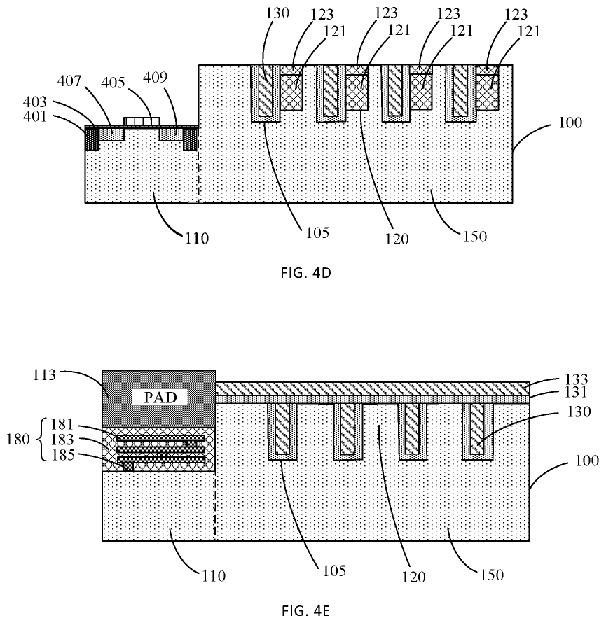

FIG. 3 illustrates a partial cross-sectional view of an image sensor in accordance with further embodiments of the present disclosure. In the figure, the same or like components are denoted by the same reference numerals, and the repeated description thereof will be omitted. As shown in FIG. 3, the image sensor may further include a connection structure 180 disposed over the logic region and a pad (PAD) 113 disposed over the connection structure. The connection structure 180 may include at least one insulating layer 183 and at least one conductive member 181. The connection structure may be disposed between the pad and the substrate (logic region) to provide electrical connection between the pad and the substrate.

In some embodiments, the conductive member 181 may be, for example, a metal layer that may be disposed in the insulating layer 183; however, the present disclosure is not limited thereto. The conductive member 181 may further include a conductive connector 185. The conductive connector 185 may be used to connect two adjacent metal layers or may be used to connect a metal layer and the active region. In other words, the conductive connector 185 may comprise via or contact. In some embodiments, the pad may comprise one or more layers of metallic materials. For example, the pad may be formed of aluminum (Al).

According to the embodiments of the present disclosure, a distance of the microlens, which is immediately adjacent to the pad, from the pad is less than or equal to 200 μm; preferably, less than or equal to 150 μm; more preferably, less than or equal to 100 μm; more preferably, less than or equal to 50 μm.

According to the embodiments of the present disclosure, the height of the top surface of the pad of the logic region is greatly reduced relative to the pixel region; even, the height of the top surface of the pad of the logic region may be substantially as high as the pixel region. Thereby, the height difference between the logic region and the pixel region is alleviated or eliminated. Therefore, the evenness of the color filter in the area around the pad is improved. Thereby, the area around the pad may also be used to form a pixel, thus increasing the effective use area of the pixel region.

According to the embodiments of the present disclosure, the area around the pad, which conventionally would otherwise not be effectively utilized, can be effectively utilized. For each pad, an effective area corresponding to a radial distance of 200-300 microns or more in its radial direction may be increased. Whereas, conventionally, this area cannot be effectively utilized.

On the other hand, according to the embodiments of the present disclosure, since the height difference between the logic region and the pixel region becomes small, the thickness of the pad can be increased, so that the reliability of wire bonding can be increased. Therefore, the yield of the image sensor can be improved.

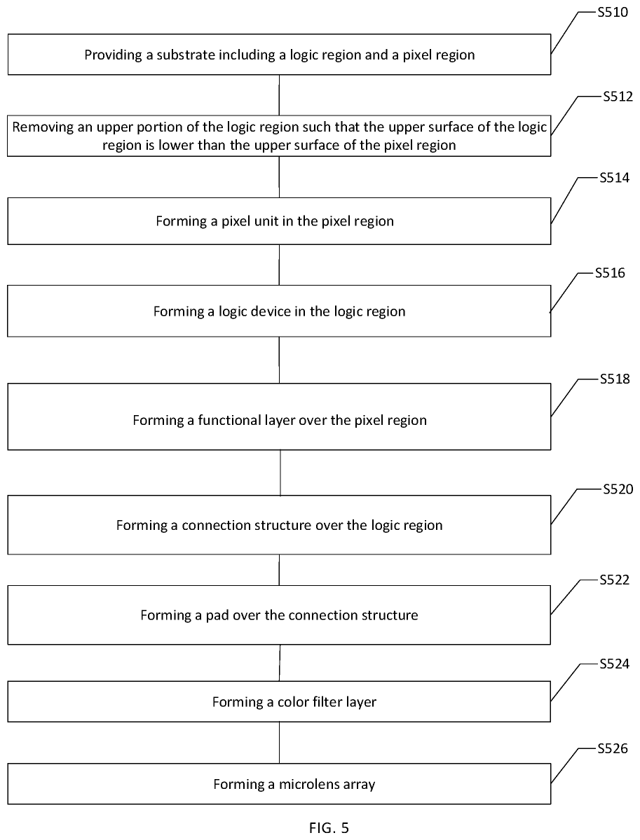

FIGS. 4A-4G show schematic partial cross-sectional views of some steps of a method of fabricating an image sensor, in accordance with some embodiments of the present disclosure. FIG. 5 illustrates a flow diagram of an exemplary method of fabricating an image sensor in accordance with some embodiments of the present disclosure. A method of fabricating image sensor according to some embodiments of the present disclosure will be described below with reference to FIGS. 4A-4G and FIG. 5.

At step S510, a substrate 100 is provided. As shown in FIG. 4A, the substrate 100 may have a first major surface 101 and a second major surface 103 opposite to the first major surface. The substrate 100 may be a semiconductor substrate. As shown in the figure, the substrate 100 may include a logic region 110 and a pixel region 150. The logic region is for forming at least a portion of an active logic device therein. The pixel region is for forming a pixel unit therein. The substrate 100 may be, for example, a P-type bulk silicon substrate; obviously, the present disclosure shall not be limited thereto.

In step S512, an upper portion of the logic region is removed such that the upper surface of the logic region is lower than the upper surface of the pixel region. As shown in FIG. 4B, in the direction from the second major surface 103 toward the first major surface 101 (i.e., from the first surface 101), the upper portion of the logic region 110 is removed, thereby causing the upper surface of the logic region 110 is lower than the upper surface of the pixel region 150.

In step S514, a pixel unit may be formed in the pixel region. The pixel unit includes at least a photosensitive element. In addition, logic devices can also be formed at the logic region.

In an implementation, as shown in FIGS. 4C-4D, trench isolations 130, such as deep trench isolation (DTI), may be formed in the pixel regions. In this embodiment, the trench isolations 130 are shown to include two layers of insulating materials; however, the present disclosure is not limited thereto.

Thereafter, photosensitive elements 120, such as photodiodes, may be formed in the pixel region. As an example, in a specific implementation, doped regions 121 may be formed in the substrate by, for example, ion implantation. The doped regions 121 may have a conductivity type opposite to that of the substrate, such as an N-type. As such, the doped regions 121 and the substrate constitute photodiodes. It should be understood that the configuration of the doped regions shown in FIG. 4C is merely exemplary, and those skilled in the art can readily set the configuration according to the needs of practical applications. Optionally, additional doped regions 123 may also be formed over the doped regions 121. The doped regions 123 may have a conductivity type opposite to that of the doped regions 121, such as a P+ type, so that the doped regions 123 may, together with the doped regions 121, form pinned diodes. The doped regions 123 can also be formed by the process such as ion implantation. In some embodiments, the doped regions 123 may be formed first, followed by the formation of the doped regions 121; or vice versa.

The method may further include: in step S516, forming a logic device in the logic region. As shown in FIG. 4D, an isolation member 401 for device isolation (e.g., shallow trench isolation (STI)) may be formed in the logic region 110. Thereafter, a gate insulating layer 403 is formed over the logic region 110, and a gate 405 is formed over the gate insulating layer. Thereafter, ion implantation may be performed in a self-aligned manner to form the source and drain 405/407 in the logic region. Obviously, the method of forming the logic device according to the present disclosure is not limited thereto, and the logic device can be formed using a variety of known materials and a variety of known processes as known to those of ordinary skill in the art, and thus the details thereof will not be further described.

It should be understood that the illustrations of the logic device and the photosensitive elements are merely illustrative and may not necessarily be drawn to scale. In these figures, certain components may be enlarged relative to other components. In addition, in the subsequent figures, details of logic devices and pixel units may be not illustrated for clarity of illustration and avoidance of blurring of other aspects.

The method may further include: in step S518, forming a functional layer over the pixel region. As shown in FIG. 4E, the functional layer may include one or more layers. In this embodiment, the functional layer may include two insulating layers 131 and 133. As previously mentioned, the functional layer may also include other layers, such as anti-reflective films and the like.

The method may further include: in step S520, forming a connection structure over the logic region from which the upper portion is removed. As shown in FIG. 4E, a connection structure 180 is formed over the logic region 110. The connection structure 180 includes at least one insulating layer 183 and at least one conductive member 181 or 185.

The method may further include: in step S522, forming a pad (PAD) 113 over the connection structure, as shown in FIG. 4E.

The method may further include: in step S524, forming a color filter layer, as shown in FIG. 4F. The color filter layer 160 may include a plurality of color filters. Each of the color filters can be disposed above a corresponding pixel unit. The functional layer is disposed between the corresponding color filter and the corresponding pixel unit.

The method may further include: in step S526, forming a microlens array, as shown in FIG. 4G. The microlens array may include a plurality of microlenses 170, each of the microlenses being disposed over a corresponding color filter.

It should be understood that the steps shown in FIGS. 4A-4G and FIG. 5 are merely exemplary and illustrative. Those skilled in the art will readily appreciate that the boundaries between the above operations are merely illustrative. Multiple operations may be combined into a single operation, a single operation may be distributed among additional operations, and operations may be performed at least partially overlapping in time. Moreover, alternative embodiments may include multiple instances of a certain operation, and the operational sequence may be varied in other various embodiments. However, other modifications, changes, and substitutions are also possible. Accordingly, the specification and drawings are to be regarded as illustrative, rather than limiting.

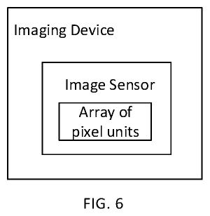

FIG. 6 illustrates a schematic block diagram of an imaging device in accordance with some embodiments of the present disclosure. As shown in FIG. 6, a device having an image sensor, such as an imaging device, is provided according the present disclosure, wherein the image sensor is an image sensor according to any of the embodiments of the present disclosure. The image sensor may include an array of pixel units. The pixel unit may include at least the photosensitive element.

The various embodiments of the present disclosure have been described as above, but the foregoing description is merely illustrative and not for enumerating all the possible embodiments of the present disclosure, and the inventions of the present disclosure shall not be limited to the specific embodiments disclosed herein. The embodiments disclosed herein can be arbitrarily combined as appropriate without departing from the spirit and scope of the present disclosure. Many modifications and variations that are apparent to those skilled in the art from the present disclosure are intended to be embraced by the spirit and scope of the present disclosure. The scopes of the inventions are to be defined by the appended claims.

What is claimed is:

1. An image sensor comprising:
a substrate including a logic region and a pixel region,
wherein the logic region is configured to form at least a portion of an active logic device therein, the pixel region is configured to form a pixel unit therein, the pixel unit including at least a photosensitive element,
wherein an upper surface of the logic region is lower than an upper surface of the pixel region.

2. The image sensor according to claim 1, further comprising:
a color filter layer, the color filter layer including a plurality of color filters each being disposed over a respective pixel unit; and
a microlens array including a plurality of microlenses each being disposed over a respective color filter.

3. The image sensor according to claim 1, wherein:
a portion of the substrate is removed to form the upper surface of the logic region.

4. The image sensor according to claim 1, further comprising:
a connection structure disposed over the logic region, the connection structure including at least one insulating layer and at least one conductive member; and
a pad disposed over the connection structure.

5. The image sensor according to claim 2, further comprising:
a connection structure disposed over the logic region, the connection structure including at least one insulating layer and at least one conductive member; and
a pad disposed over the connection structure,
wherein a distance between the pad and a microlens which is immediately adjacent to the pad is less than or equal to 200 μm.

6. The image sensor according to claim 1, further comprising:
a functional layer over the pixel region, the functional layer comprising at least an insulating layer.

7. The image sensor according to claim 1, further comprising:
a functional layer over the pixel region;
a color filter layer including a plurality of color filters each being disposed over a respective pixel unit, the functional layer being disposed between corresponding color filter(s) and corresponding pixel unit(s); and
a microlens array including a plurality of microlenses each being disposed over a respective color filter.

8. A method for fabricating an image sensor, comprising:
providing a substrate having a first major surface and a second major surface opposite to the first major surface, the substrate including a logic region and a pixel region, the logic region for forming at least a portion of an active logic device therein, and the pixel region for forming a pixel unit therein;
removing an upper portion of the logic region in a direction from the second major surface toward the first major surface such that an upper surface of the logic region is lower than an upper surface of the pixel region; and
forming a pixel unit in the pixel region, wherein the pixel unit includes at least a photosensitive element.

9. The method according to claim 8, further comprising:
forming part of or all of the active logic device in the logic region where the upper portion is removed.

10. The method according to claim 8, further comprising:
forming a functional layer over the pixel region, the functional layer including at least an insulating layer.

11. The method according to claim 8, further comprising:
forming a color filter layer including a plurality of color filters each of which is disposed over a respective pixel unit;
forming a microlens array including a plurality of microlenses each of which is disposed over a respective color filter.

12. The method according to claim 10, further comprising:
forming a color filter layer including a plurality of color filters each of which is disposed over a respective pixel unit, the functional layer being disposed between corresponding color filter(s) and corresponding pixel unit(s);
forming a microlens array including a plurality of microlenses each of which is disposed over a respective color filter.

13. The method according to claim 8, further comprising:
forming a connection structure over the logic region from which the upper portion is removed, the connection structure including at least one insulating layer and at least one conductive member; and
forming a pad over the connection structure.

14. The method according to claim 11, further comprising:
forming a connection structure over the logic region from which the upper portion is removed, the connection structure including at least one insulating layer and at least one conductive member; and
forming a pad over the connection structure,
wherein a distance between the pad and a microlens directly adjacent to the pad is less than or equal to 200 μm.

15. The method according to claim 12, further comprising:
forming a connection structure over the logic region from which the upper portion is removed, the connection structure including at least one insulating layer and at least one conductive member; and
forming a pad over the connection structure,
wherein a distance between the pad and a microlens directly adjacent to the pad is less than or equal to 200 μm.

16. The method according to claim 8, wherein forming a pixel unit in the pixel region comprises:
forming a trench in the pixel region to separate the pixel units; and
forming a photosensitive element of the pixel unit in a region of the pixel region separated by the trench.

17. An apparatus comprising an image sensor according to claim 1.
